(19) United States
(12) Patent Application Publication
(10) Pub. No.: US 2008/0012592 A1
(43) Pub. Date: Jan. 17, 2008

(54) DEVICE AND METHOD FOR TESTING SEMICONDUCTOR PACKAGES

(75) Inventors: Yoon-gyu SONG, Suwon-si (KR); Woo-jin JANG, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/760,847

(22) Filed: Jun. 11, 2007

(30) Foreign Application Priority Data
Jul. 13, 2006 (KR) 10-2006-0065874

(51) Int. Cl. G01R 31/02; H01R 12/14

(52) U.S. Cl. 324/755; 324/537; 324/758; 324/765; 439/71

(57) ABSTRACT

A socket for testing a semiconductor package comprises two or more rubbers. Each rubber includes a chip-package contact portion configured to electrically connect with a chip package placed on the rubber and electrical wirings configured to electrically connect with the chip-package contact portion and having external contact ends configured to electrically connect with external electrical connections. The socket also comprises two or more guides configured to receive the chip package therein, the two or more guides including electrical wirings having external contact ends that are configured to be electrically connected with external electrical connections and a socket frame configured to hold the two or more rubbers and the two or more guides, wherein the rubbers correspond in number to the guides, and the rubbers and the guides are alternately stacked so that one rubber is located at a lowermost portion in a holding space of the socket frame.

### BACKGROUND OF THE INVENTION

1. Field of the Invention

The present disclosure relates generally to semiconductor packages and, more particularly, to devices and methods for testing semiconductor packages.

A claim of priority is made to Korean Patent Application No. 10-2006-0065874, filed on Jul. 13, 2006, in the Korean Intellectual Property Office, the disclosure of which is incorporated herein in its entirety by reference.

2. Description of the Related Art

Semiconductor fabrication involves a number of steps. For example, a circuit is first designed, then a process of implementing the circuit is selected, and the circuit is eventually fabricated on a wafer using the selected process. In addition, after fabrication of the semiconductor chip, the wafer is tested to identify potential defects. The defects are then rectified. After the defects are rectified, if a single-layer semiconductor package is to be formed, the package is created. Alternatively, if a multi-chip package is to be formed, the above-mentioned processes may be performed repeatedly to obtain the desired semiconductor package.

In recent years, multi-chip packages are increasingly being used in order to improve the integration density of semiconductor devices. Basically, in multi-chip packages, a number of semiconductor wafers are stacked one on top of another and housed in the same package. Such a design helps reduce the size of devices using semiconductor chips because a number of semiconductor packages, each including only one chip, can now be replaced by a single multi-chip package including a number of chips. However, if semiconductor chips are stacked one on top of the other, there may be problems such as, for example, electromagnetic interference between the devices. Therefore, it may be beneficial to stack several single-layer semiconductor packages one on top of another rather than stacking the semiconductor chips one on top of another.

While multi-chip packages are being increasingly manufactured, most systems used to test semiconductor packages are designed to test single-layer layer semiconductor packages only. For example, FIG. 1A is a side cross-sectional view illustrating a conventional socket 110 which tests a single-layer semiconductor package. The socket 110 includes a lid 110A and a socket frame 110B. Furthermore, a rubber 130 is located at a lower portion in the socket frame 110B, and a guide 120 is located on the rubber 130. A chip package 140 is located in the guide 120.

To test the chip package 140, the lid 110A of the socket 110 of FIG. 1A is opened, the guide 120 is mounted inside the socket 110, and then the chip package 140 is put into a chip package receiving space inside the guide 120 (see FIG. 1B). Then, the lid 110A is closed and several electrical and/or physical tests are performed through a test bench 101. The test bench 101 is electrically connected to the chip package 140. Specifically, the test bench 101 connects to the chip package 140 through a rubber 130.

The rubber 130 supports the chip package 140 received in the guide 120 and serves as an interface between the chip package 140 and the underlying test bench 101 for an electrical connection therebetween. That is, as shown in FIG. 1A, the chip package 140 is electrically connected with the test bench 101 via rubber wirings 134. These rubber wirings 134 may send and receive an electrical signal to and from the test bench 101. For example, when the chip package is a ball grid array (BGA) package, the rubber 130 may include pop-ups 132 thereon to provide an electrical contact between the test bench 101 and the chip package 140 (see FIG. 3).

Referring to FIG. 2, the guide 120 is configured to receive the chip package 140 and has an internal receiving space having a size corresponding to the chip package 140. Furthermore, the lid 110A of the socket 110 seals the internal test space, thereby ensuring the reliability of a test result. Particularly, as shown in FIG. 1A, a holder 112 is formed at a center of the lid 110A for pressing and fixing the chip package. The holder 112 may further include a hollow portion 114 in a central portion thereof for a heat/cold-resistance test.

With such a conventional socket, it may be possible to test a multi-chip semiconductor package having a structure in which several semiconductor devices are stacked in one package. However, it may be impossible to test several single-layer semiconductor packages that are stacked one on top of another. There is therefore a need for a socket which can be used to test several single-layer semiconductor packages at a time.

The present disclosure is directed towards a device and methods for testing stacked single-layer semiconductor packages.

### SUMMARY OF THE INVENTION

An aspect of the present disclosure includes a socket for testing a semiconductor package. The socket comprises two or more rubbers. Each rubber includes a chip-package contact portion configured to electrically connect with a chip package placed on the rubber and electrical wirings configured to electrically connect with the chip-package contact portion and having external contact ends configured to electrically connect with external electrical connections. The socket also comprises two or more guides configured to receive the chip package therein, the two or more guides including electrical wirings having external contact ends that are configured to be electrically connected with external electrical connections and a socket frame configured to hold the two or more rubbers and the two or more guides, wherein the rubbers correspond in number to the guides, and the rubbers and the guides are alternately stacked so that one rubber is located at a lowermost portion in a holding space of the socket frame.

Another aspect of the present disclosure includes a rubber in a socket which tests a package. The rubber comprises a chip-package contact portion configured to electrically connect with a chip package placed on the rubber and electrical wirings configured to electrically connect with the chip-package contact portion and having external contact ends configured to electrically connect with external electrical connections.

Yet another aspect of the present disclosure includes a guide configured to receive a chip package. The guide comprises electrical wirings including external contact ends configured to electrically connect with external electrical connections.

Another aspect of the present disclosure includes a method of testing semiconductor packages. The method comprises alternately stacking, on a test bench, two or more rubbers and two or more guides for receiving and testing chip packages, wherein each rubber comprises a chip-package contact portion configured to electrically connect with a chip package placed on the rubber, and electrical wirings configured to electrically connect with the chip-package contact portion and having external contact ends that are configured to electrically connect with external electrical wirings and each guide comprises electrical wirings including external contact ends that are configured to be electrically connected with external electrical connections.

### BRIEF DESCRIPTION OF THE DRAWINGS

The above and other features of the present disclosure will become more apparent by describing in detail exemplary embodiments thereof with reference to the attached drawings in which:

FIGS. 1A and 1B are cross-sectional and perspective views of a conventional socket for testing a package, respectively;

FIG. 2 is a perspective view illustrating a guide used in a conventional socket for testing the package of FIG. 1;

FIG. 3 is a perspective view illustrating a rubber used in a conventional socket for testing the package of FIG. 1;

FIG. 4 is a side cross-sectional view illustrating a socket for testing a package according to an exemplary disclosed embodiment;

FIGS. 5A and 5B are perspective and side cross-sectional views, respectively of a guide for a socket for testing a package according to an exemplary disclosed embodiment;

FIGS. 6A and 6B are perspective and side cross-sectional views, respectively of a rubber for a socket for testing a package according to an exemplary disclosed embodiment; and

FIGS. 7 and 8 are side cross-sectional views of a socket for testing a package according to an alternative exemplary disclosed embodiment.

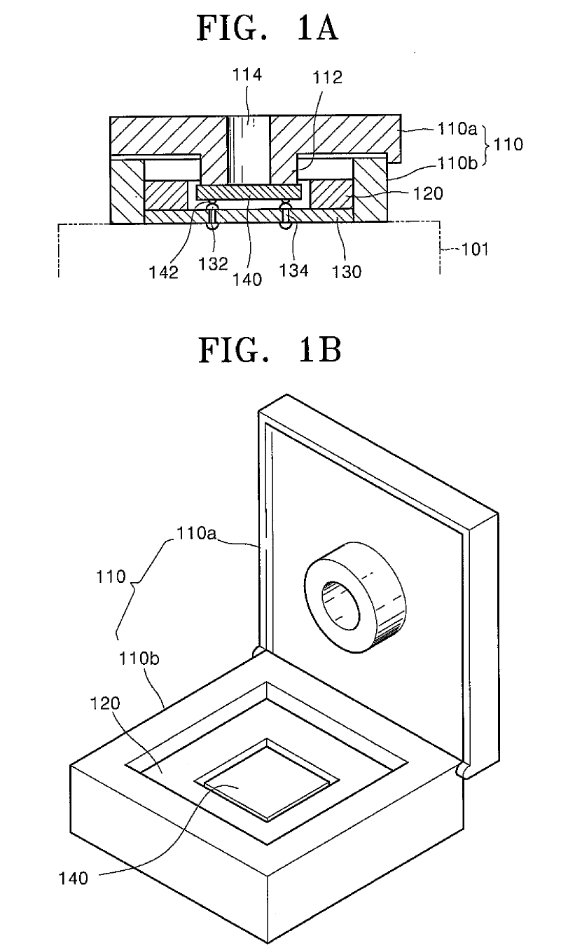

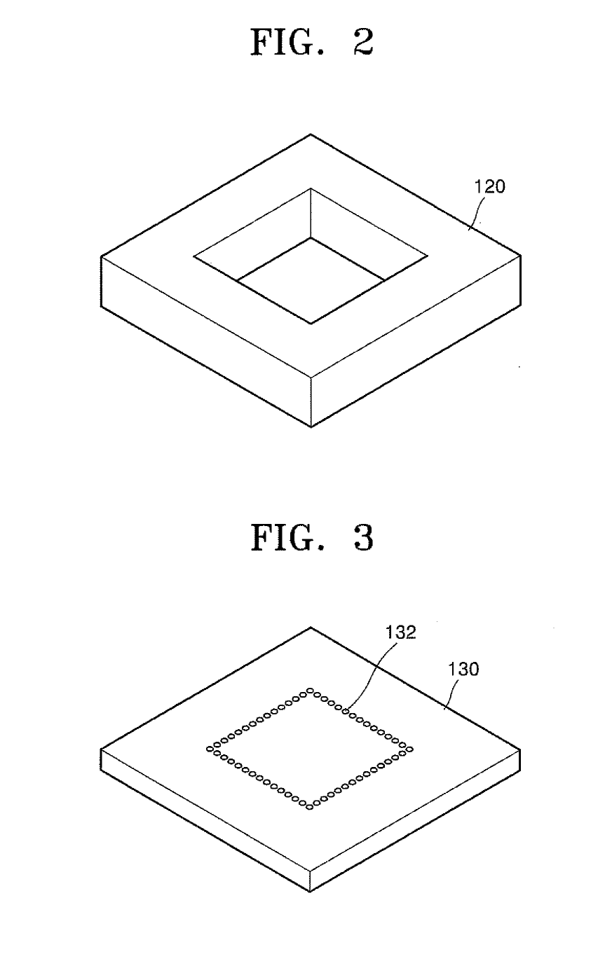

### DETAILED DESCRIPTION OF EMBODIMENTS

The present disclosure will now be described more fully hereinafter with reference to the accompanying drawings, in which exemplary embodiments of the disclosure are shown. This disclosure may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification. Furthermore, various elements and regions in the drawings are drawn in a schematic manner. Accordingly, the present disclosure is not limited by the relative sizes and intervals of the accompanying drawings.

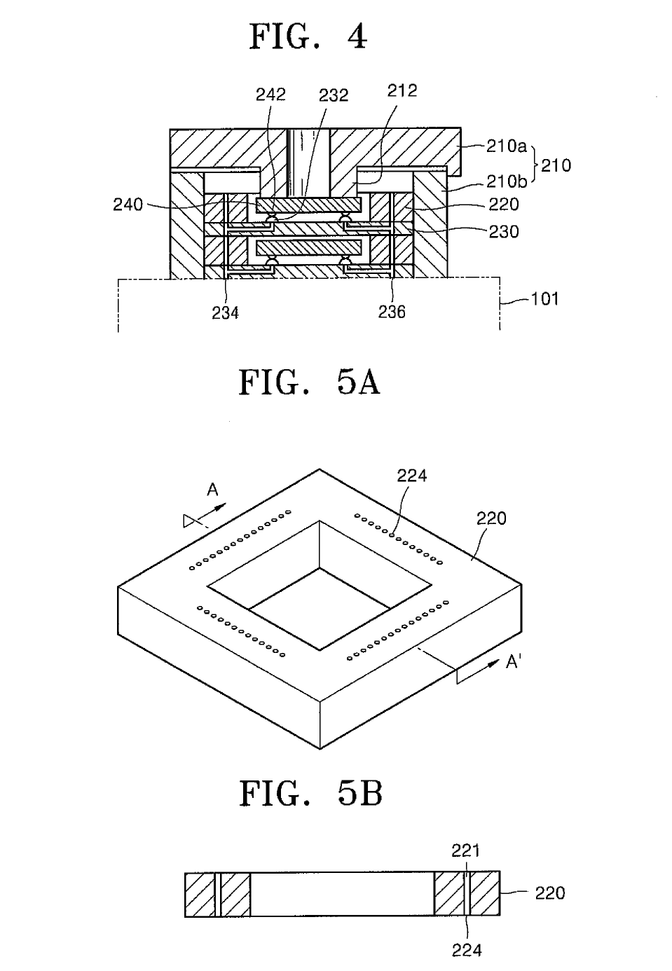

FIG. 4 is a side cross-sectional view illustrating a socket 210 for testing a semiconductor package according to an exemplary disclosed embodiment. Typically, the package tested includes a plurality of single-layer packages stacked over each other. In an exemplary embodiment, the package test socket 210 includes a lid 210a and a socket frame 210b. Furthermore, the socket frame 210b has an internal space which receives components that may be used for testing the package. These components may include, for example, rubbers 230 and guides 220. Moreover, in an exemplary embodiment, two or more rubbers 230 and two or more guides 220 are alternately stacked in the internal space of the socket frame 210b.

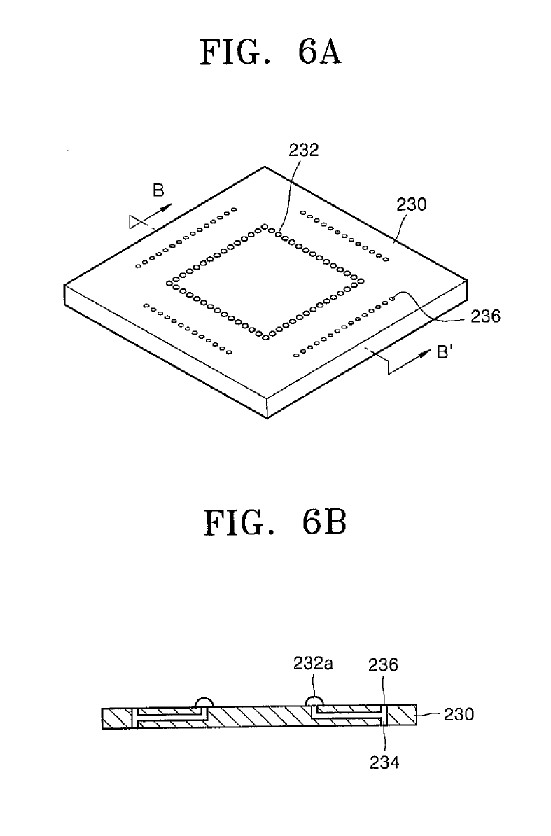

In an exemplary embodiment, a chip package 240 that needs to be tested is placed on the rubber 230. The rubber 230 includes a chip-package contact portion 232 that can be electrically connected with the chip package 240, as shown in FIGS. 6A and 6B. In particular, the chip-package contact portion 232 may be brought into electrical contact with contact ends, such as solder balls, formed on the bottom of the chip package 240.

The rubber 230 further includes electrical wirings 234. Typically, these electrical wirings 234 are electrically connected with the chip-package contact portion 232. Furthermore, these wirings 234 have external contact ends 236 that are electrically connected with external electrical wirings. In an exemplary embodiment, the electrical wirings 234 of the rubber 230 may be formed of an electrically conductive material, and other portions thereof may be formed of a nonconductive material.

Each electrical wiring 234 of the rubber 230 may include an external contact end 236 exposed to an upper surface of the rubber 230 and an external contact end 236 exposed to a lower surface of the rubber. Furthermore, the external contact end 236 exposed to the upper surface of the rubber 230 is connected with an external contact end 236 exposed to a lower surface of the guide 220 located on the rubber 230. In addition, the external contact end 236 exposed to the lower surface of the rubber 230 may be connected with an external contact end 236 exposed to the upper surface of the underlying guide 220.

Specifically, in each electrical wiring 234, the external contact end 236 exposed to the upper surface of the rubber 230 may be connected with the external contact end 236 exposed to the lower surface of the rubber in a direction perpendicular to the upper surface of the rubber 230. Furthermore, the electrical wiring may extend to the chip-package contact portion 232. For example, the electrical wiring 234 may extend from a lower portion of the chip-package contact portion 232 that is parallel to the upper surface of the rubber 230, vertically towards the surface of the rubber 230, such that the external contact ends 236 are connected with the chip-package contact portion 232.

Referring to FIG. 6B, if the chip package 240 is a ball grid array (BGA) package, the chip-package contact portion 232 may include a pop-up 232a. Pop-up 232a is generally formed thereon for easy contact with the chip package 240.

As shown in FIG. 6A, the rubber 230 includes the external contact end 236 which electrically connects the chip-package contact portion 232 and the guides 220 located on and/or beneath the rubber 230. Because the chip package 240 may come in different sizes, the chip-package contact portion 232 may be laid out in a rhombic lattice form, but is not limited thereto. Furthermore, the external contact end 236 may be laid out in different shapes and forms to correspond to the layout of the chip-package contact portion 232 and, therefore, is not limited to the layout of FIG. 6A. However, the external contact end 236 that is exposed to the lower surface of the lowermost rubber 230 must be laid out in such a manner that it is electrically connected with the test bench 101.

Referring to FIGS. 5A and 5B, the guide 220 includes an internal space which receives the chip package 240. In particular, the guide serves to horizontally hold the chip package 240. Therefore, the space for accommodating the chip package 240 may be changed according to the size of the chip package 240.

The guide 220 further includes electrical wirings 221 including external contact ends 224 that can be electrically connected with external electrical wirings. Furthermore, in an exemplary embodiment, the electrical wirings 221 of the guide 220 may be formed of an electrically conductive material, and other portions thereof may be formed of a non-conductive material.

Each electrical wiring 221 of the guide 220 may include an external contact end exposed to an upper surface of the guide 220 and an external contact end exposed to a lower surface of the guide. The external contact end exposed to the upper surface of the guide 220 may be connected with the external contact end exposed to the lower surface of the guide in a direction perpendicular to the upper surface of the guide.

The guide 220 has a height higher than or identical to that of the chip package 240 received therein. Alternatively, when the pop-up 232a is formed on the chip-package contact portion 232 of the rubber 230 located beneath the guide 220, the height of the guide 220 may be greater than or identical to the height of the chip package 240 plus the height of the pop-up 232a.

As described above, in an exemplary embodiment, two or more rubbers 230 and two or more guides 220 are alternately stacked in the internal space of the socket frame 210b. Furthermore, the lowest rubber 230 is located in the lowermost portion of the internal space and the uppermost guide 220 is located in the uppermost portion of the internal space.

Referring to FIG. 4, a holder 212 may be located over the uppermost guide 220. Furthermore, the holder 212 may be configured to hold the chip package 240 received in the uppermost guide 220 by pressing it toward the test bench 101. In an exemplary embodiment, the holder may be formed such that it is an integral portion of the lid 210a. For example, the holder may be molded together with the lid 210a. Alternatively, as shown in FIG. 4, the lid 210a may be coupled to the socket frame 210b through a hinge structure. However, one skilled in the art will appreciate that the scope of this disclosure is not limited to the above-described configurations of the lid 210a and the holder 212. That is, any other configuration of the holder 212 and the lid 210a may be used to hold the chip package 240 without departing from the scope of the present disclosure. Furthermore, although exemplary embodiments have been described in connection with the package test socket in which two chip packages are stacked as shown in FIGS. 4, 5A, 5B, 6A, and 6B, three or more chip packages may also be stacked in the disclosed socket without departing from the scope of the disclosure.

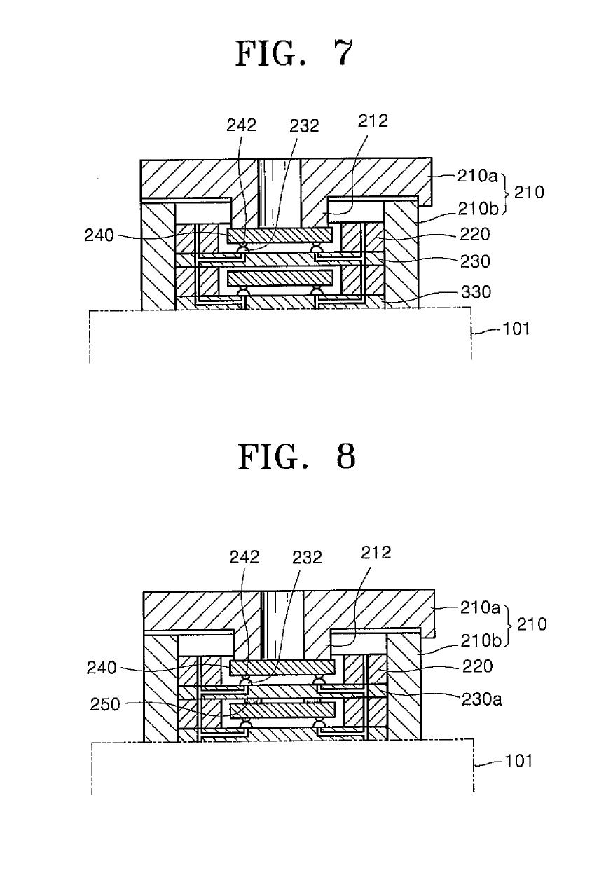

An alternative exemplary embodiment will now be described with reference to FIG. 7. Referring to FIG. 7, the electrical wiring is configured as follows. A chip-package contact portion of the lowermost rubber 330 is connected with an external contact end. This external contact end is exposed to a lower surface of the rubber 330 in a direction perpendicular to the upper surface of the rubber 330. The electrical wiring extends from an electrical wiring connection between the chip-package contact portion and the external contact end exposed to the lower surface of the rubber 330 to a lower portion of the external contact end exposed to the upper surface of the rubber 330. Furthermore, the electrical wiring extends from the lower portion of the external contact end exposed to the upper surface of the rubber 330 in a direction that is perpendicular to the upper surface of the rubber 330, such that the electrical wiring is connected with the external contact end exposed to the upper surface of the rubber 330.

A comparison between the rubber disclosed in exemplary embodiments and a conventional rubber reveals that the chip-package contact portion of the rubber according to exemplary disclosed embodiments may have an interval greater than that of the conventional rubber. In this case, the rubber may not match the underlying test bench 101, which may require changing the design of the test bench 101. However, by designing the electrical wirings of the lowermost rubber according to exemplary disclosed embodiments, the existing test bench 101 can be used without changing the design.

An alternative exemplary embodiment will now be described with reference to FIG. 8. Referring to FIG. 8, each of the rubbers 230a other than a lowermost rubber may further include a rubber holder 250 that faces an underlying chip package.

If the rubber 230a does not include the rubber holder 250, the pressure applied downward by the holder 212 may not be well delivered to the underlying chip package 240. This may especially be the case when the guide 220 located below the rubber 230 does not exactly correspond in height to the chip package 240 received in the guide 220

The rubber holder 250 may be a part of the rubber 230a and is located to face the underlying chip package 240. Because the rubber 230a is not located at a lowermost portion as previously mentioned, the guide 220 and the chip package 240 received in the guide 220 are located below the rubber 230a. As described above, the guide 220 includes a space for receiving the chip package 240. The chip package 240 is received in the space and, in this case, the rubber holder 250 is located at a rubber 230a portion corresponding to the space.

Beneficially, the rubber holder 250 is formed of an elastic material that can be flexibly adapted to a height deviation between the guide 220 and the chip package 240. For example, the elastic material is a rubber material, an elastic polymer material, or the like but is not particularly limited to these materials as long as the material used has elasticity.

The rubber holder 250 may have a height equal to or greater than a difference in height between the underlying guide and the chip package received in the guide. More specifically, the rubber holder 250 may have a height that can be compressed to the difference in height by a force generated when the holder 212 presses downwards.

An alternative exemplary embodiment discloses a package testing method that can provide the same results as those produced in the testing of a multi-chip semiconductor package by testing stacked single-layer semiconductor packages instead.

The method of testing packages includes alternately stacking on a test bench, two or more rubbers for a test socket and two or more guides for the test socket with chip packages received therein. Each rubber comprises a chip-package contact portion that can be electrically connected with a chip package placed on the rubber. Each rubber also includes electrical wirings electrically connected with the chip-package contact portion and having external contact ends that can be electrically connected with external electrical wirings. Furthermore, each guide also comprises electrical wirings including external contact ends that can be electrically connected with external electrical wirings.

By using the disclosed package test socket, it may be possible to obtain a test result of a multi-chip semiconductor package using single-chip semiconductor packages that are stacked on each other, without having to fabricate the multi-chip semiconductor package for testing purposes.

While the present disclosure has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A socket for testing a semiconductor package, comprising:
two or more rubbers, each rubber including (a) a chip-package contact portion configured to electrically connect with a chip package placed on the rubber, and (b) electrical wirings configured to electrically connect with the chip-package contact portion and including external contact ends configured to electrically connect with external electrical connections;
two or more guides configured to receive the chip package therein, the two or more guides including electrical wirings including external contact ends that are configured to be electrically connected with external electrical connections; and
a socket frame configured to hold the two or more rubbers and the two or more guides, wherein the rubbers correspond in number to the guides, and the rubbers and the guides are alternately stacked so that one rubber is located at a lowermost portion in a holding space of the socket frame.

2. The socket of claim 1, further comprising a holder located over the uppermost guide, the holder being configured to hold the chip package received in the guide by pressing the chip package towards a test bench.

3. The socket of claim 1, wherein each electrical wiring of the rubber comprises an external contact end exposed to an upper surface of the rubber and an external contact end exposed to a lower surface of the rubber.

4. The socket of claim 3, wherein each electrical wiring of the guide comprises an external contact end exposed to an upper surface of the guide and an external contact end exposed to a lower surface of the guide.

5. The socket of claim 4, wherein when the guide and the rubber are received in the socket frame, the external contact end exposed to the lower surface of the guide is electrically connected with the external contact end exposed to the upper surface of the rubber.

6. The socket of claim 4, wherein when the guide and the rubber are received in the socket frame, the external contact end exposed to the upper surface of the guide is electrically connected with the external contact end exposed to the lower surface of the rubber.

7. The socket of claim 1, wherein the external contact end exposed to a lower surface of the lowermost rubber is electrically connected with a test bench.

8. A rubber in a socket which tests a package, the rubber comprising:
a chip-package contact portion configured to electrically connect with a chip package placed on the rubber; and
electrical wirings configured to electrically connect with the chip-package contact portion and having external contact ends configured to electrically connect with external electrical connections.

9. The rubber of claim 8, wherein each electrical wiring of the rubber comprises an external contact end exposed to an upper surface of the rubber and an external contact end exposed to a lower surface of the rubber.

10. The rubber of claim 9, wherein the external contact end exposed to the upper surface of the rubber is connected with the external contact end exposed to the lower surface of the rubber and each electrical wiring extends to a lower portion of the chip-package contact portion in a direction parallel to the upper surface of the rubber, and then from the lower portion of the chip-package contact portion vertically towards the surface of the rubber, such that each electrical wiring is connected with the chip-package contact portion.

11. The rubber of claim 9, wherein the chip-package contact portion of the rubber is connected with the external contact end exposed to the lower surface of the rubber and the electrical wiring extends from an electrical wiring connecting the chip-package contact portion and the external contact end exposed to the lower surface of the rubber to a lower portion of the external contact end exposed to the upper surface of the rubber, and then from the lower portion of the external contact end exposed to the upper surface of the rubber vertically towards the upper surface of the rubber, such that the electrical wiring is connected with the external contact end exposed to the upper surface of the rubber.

12. The rubber of claim 8, wherein a portion of the electrical wirings is made of conductive material and the remaining portion of the electrical wirings is made of non-conductive material.

13. The rubber of claim 8, wherein the rubber further comprise a rubber holder place above an underlying chip package.

14. A guide configured to receive a chip package, the guide comprising electrical wirings including external contact ends configured to electrically connect with external electrical connections.

15. The guide of claim 14, wherein each electrical wiring of the guide comprises an external contact end exposed to an upper surface of the guide and an external contact end exposed to a lower surface of the guide.

16. The guide of claim 15, wherein in each electrical wiring, the external contact end exposed to the upper surface of the guide is connected vertically towards the upper surface with the external contact end exposed to the lower surface of the guide.

17. The guide of claim 14, wherein the guide has a height greater than or equal to that of the chip package received therein.

18. A method of testing semiconductor packages comprising:
alternately stacking, on a test bench, two or more rubbers and two or more guides for receiving and testing chip packages; wherein:
each rubber comprises a chip-package contact portion configured to electrically connect with a chip package placed on the rubber, and electrical wirings configured to electrically connect with the chip-package contact portion and having external contact ends that are configured to electrically connect with external electrical wirings, and
each guide comprises electrical wirings including external contact ends that are configured to be electrically connected with external electrical connections.

19. The method of claim 18, further comprising holding the chip package received in an uppermost guide among the alternately stacked rubbers and guides using a holder.
